(19) United States
(12) Patent Application Publication
(10) Pub. No.: US 2005/0157472 A1
(43) Pub. Date: Jul. 21, 2005

(54) Slot filler with capability to control electronic cooling air recirculation

(75) Inventors: Christopher G. Malone, Loomis, CA (US); Glenn C. Simon, Auburn, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 10/759,856

(22) Filed: Jan. 15, 2004

(51) Int. Cl. H05K 5/00

(52) U.S. Cl. 361/724; 361/688

(57) ABSTRACT

A slot filler for usage in a rack cabinet can accept a plurality of stacked electronic devices. The cabinet has an air inlet and exit on mutually opposing sides and a plurality of slots capable of securing the stacked electronic devices. The slot filler comprises a blanking panel capable of covering an entry opening of a slot that is unoccupied by an electronic device, and a body coupled to the blanking panel that emulates dimensions of an electronic device and has a thickness selected so that clearance between the slot filler and an adjacent electronic device leaves an air flow gap from the air inlet to exit that is sufficiently small to create an air flow resistance preventing air from re-circling toward the air inlet.

### BACKGROUND OF THE INVENTION

Electronic systems and equipment such as computer systems, network interfaces, storage systems, and telecommunications equipment are commonly enclosed within a cabinet or housing for support, physical security, and efficient usage of space. Electronic equipment contained within the enclosure generates a significant amount of heat. Thermal damage may occur to the electronic equipment unless the heat is removed.

Low-profile computer system installations present significant thermal management difficulties. For example, Electronics Industry Association (EIA) standard racks are commonly used to house electronic equipment. In relatively large systems, for example 2U or larger where “U” is the measuring unit for racks and rack-mountable components with 1U=1.75″ or 44.45 mm, most cooling air enters through the front of the enclosure and exits through the rear. For low-profile systems, the enclosure front is significantly blocked by hard drives and media devices. The rear is blocked by power supplies and input/output (I/O) connectors. To lower air flow resistance through the enclosure and enhance cooling, typical 1U and 2U servers use a perforation on the top of the enclosure to supply cooling air and to vent heated exhaust. In a rack fully loaded with standard electronic equipment 1U and 2U devices, such as servers, computers, I/O equipment, and the like, a small clearance is interposed between adjacent stacked devices. For example, in some systems approximately 0.050 inches of clearance separates the devices. The small space between systems permits fresh air from the room to enter near the front of the enclosure and warmed air to exhaust near the rear through separate perforation patterns in the enclosure. In typical systems, the inlet perforations and exit perforations are separated by more than twelve inches. The small gap between systems creates a very high air flow resistance, preventing air from re-circulating between the air supply and exhaust.

Re-circulation of heated air can impact performance of electronic equipment. If airflow patterns allow re-usage of air that is previously heated by electronic equipment, attempts to cool electronic equipment can fail and less effective heat transfer from the equipment to the cooling airflow can result. In some circumstances insufficient heat transfer can take place and the equipment may overheat and potentially sustain thermal damage.

A common re-circulation scenario occurs when a rack is not completely filled with electronic devices. If an open space is interposed in a slot above an electronic device, hot air exhausted from the device may re-circulate back to the vicinity of the air inlet, greatly impacting thermal management for device. Given the power densities of 1U and 2U electronic equipment and the challenges of effectively attaining room-level cooling for these devices, racks are commonly underpopulated. Accordingly, air re-circulation is commonly experienced in an information technology setting.

Typically, open rack slots are filled with filler panels, generally 1U in vertical height. The filler panels have a primarily cosmetic function but also assist in prevention of hot air from re-circulating out of the enclosure to the front of the rack. Filler panels attach to front columns of the rack and do not extend into the rack.

### SUMMARY

What are desired are an apparatus and operating method that reduce or eliminate re-circulation of heated exhaust air from electronic devices.

In accordance with an embodiment of an electronic system, a slot filler can be used in a rack cabinet capable of accepting a plurality of stacked electronic devices. The cabinet has an air inlet and exit on mutually opposing sides and a plurality of slots capable of securing the stacked electronic devices. The slot filler comprises a blanking panel capable of covering an entry opening of a slot that is unoccupied by an electronic device, and a body coupled to the blanking panel that emulates dimensions of an electronic device and has a thickness selected so that clearance between the slot filler and an adjacent electronic device leaves an air flow gap from the air inlet to exit that is sufficiently small to create an air flow resistance preventing air from re-circling toward the air inlet.

In accordance with other embodiments, a system comprises a rack cabinet capable of holding a plurality of stacked electronic devices, an air inlet and exit coupled to mutually opposing sides of the cabinet, a plurality of slots contained within the cabinet and capable of securing the stacked electronic devices, and a slot filler. The slot filler comprises a blanking panel capable of covering an entry opening of a slot that is unoccupied by an electronic device, and a body coupled to the blanking panel that emulates dimensions of an electronic device and has a thickness selected so that clearance between the slot filler and an adjacent electronic device leaves an air flow gap from the air inlet to exit that is sufficiently small to create an air flow resistance preventing air from re-circling toward the air inlet.

In accordance with further embodiments, a method of controlling airflow in an electronic system comprises encasing a plurality of electronic devices in a housing having multiple slots for receiving the electronic devices arranged in a stack, and directing a cooling airstream flow over the plurality of stacked electronic devices from an air inlet to an exit. The method further comprises inserting a slot filler within any slots unoccupied by electronic devices between the plurality of stacked electronic devices, and arranging the plurality of stacked electronic devices and slot fillers with a selected clearance between adjacent electronic devices and/or slot fillers leaving an air flow gap from the air inlet to exit that is sufficiently small to create an air flow resistance preventing air from re-circling toward the air inlet.

According to additional embodiments, a system comprises a housing with a plurality of slots regularly arranged in a stack for receiving multiple electronic devices. The housing has an air inlet and an air exit for passing cooling air through the electronic devices. The system further comprises at least one electronic device inserted into at least one of the plurality of slots, and at least one slot filler inserted into the a slot of the plurality of slots. The slot fillers having dimensions that emulate dimensions of an electronic device. The electronic devices and the slot fillers have an arrangement when inserted into the slots so that clearance between the adjacent slot fillers and/or electronic device is an air flow gap that extends from the air inlet to the air exit that is sufficiently small to create an air flow resistance preventing air from re-circling toward the air inlet.

### BRIEF DESCRIPTION OF THE DRAWINGS

Embodiments of the invention relating to both structure and method of operation, may best be understood by referring to the following description and accompanying drawings.

FIG. 1 is a perspective pictorial diagram that illustrates an embodiment of a slot filler that can be used in an electronic system to prevent recirculation of heated exhaust air and thereby facilitate cooling.

FIG. 2 is a perspective pictorial diagram showing an embodiment of the slot filler with a body thickness selected to create an air flow resistance preventing air from re-circling toward the air inlet.

FIGS. 3A, 3B, and 3C are multiple perspective pictorial views showing examples of slot filler embodiments.

FIGS. 4A, 4B, and 4C are multiple perspective pictorial views showing examples of adjustable-length slot filler embodiments.

FIG. 5 is a perspective pictorial diagram that depicts an embodiment of a system that can utilize one or more slot fillers.

FIGS. 6A and 6B are a pair of perspective pictorial diagrams showing examples of cabinets that can be used in system embodiments using one or more slot fillers.

FIGS. 7A and 7B are frontal pictorial diagrams illustrating examples of electronic systems that can use the illustrative slot fillers to control exhaust air re-circulation.

### DETAILED DESCRIPTION

A slot filler comprising a filler panel and a body or member that couples to the filler panel prevents or substantially reduces re-circulation of heated air in an electronic system. The body or member, for example a sheet metal or plastic piece, extends into the rack a length that approximates the length of a typical rack-mounted electronic device, for example approximately 26 inches for a standard EIA rack. In some examples, the body or member may form a box structure, approximately 1U in height, extending approximately 26 inches in depth into the rack or cabinet. In other embodiments, the body may be a thin piece of material, anchored to the cabinet front panel, with suitable rigidity and strength to maintain a high air flow resistance within the enclosure. The body can be fabricated in a manner that the length is adjustable to accommodate adjacent products with different lengths. Various common adjustment techniques may be used. The slot filler emulates the effect on air flow of the presence of an adjacent electronic device and eliminates or greatly reduces potential risk of air re-circulation within the rack.

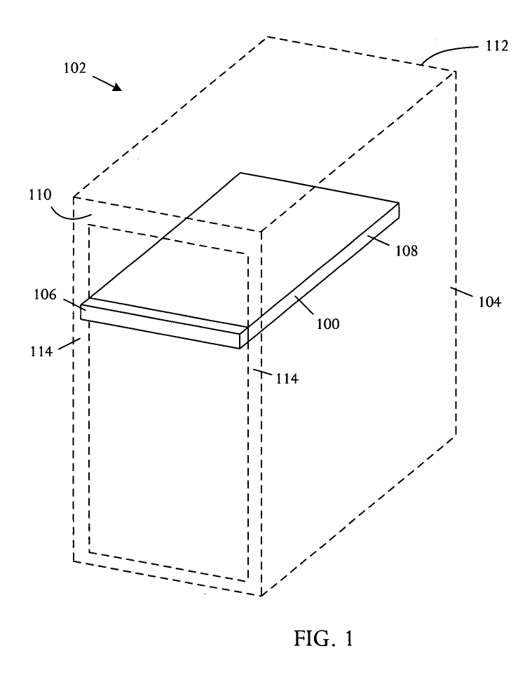

Referring to FIG. 1, a perspective pictorial diagram illustrates an embodiment of a slot filler 100 that can be used in an electronic system 102 to prevent recirculation of heated exhaust air and thereby facilitate cooling. The slot filler 100 can be used in a rack cabinet 104, illustratively depicted by dashed lines, that can accept a plurality of stacked electronic devices. The cabinet has an air inlet and exit on mutually opposing sides and a plurality of slots capable of securing the stacked electronic devices. The slot filler 100 comprises a blanking panel 106 capable of covering an entry opening of a slot that is unoccupied by an electronic device, and a body 108 coupled to the blanking panel 106 having a form factor and dimensions that emulate the structure of an electronic device. The body 108 is coupled to the blanking panel 106 at any suitable angle, for example at a perpendicular angle and other angles, to suit the structure of the rack cabinet 104.

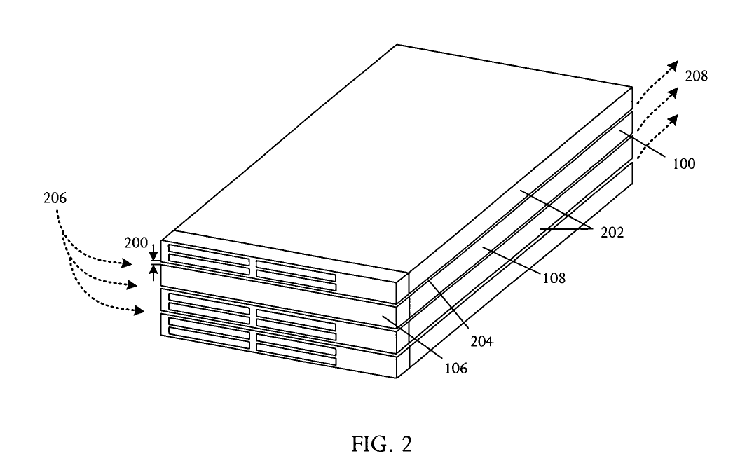

Referring to FIG. 2, a perspective pictorial diagram illustrates that the body thickness is selected so that clearance 200 between the slot filler 100 and an adjacent electronic device 202 leaves an air flow gap 204 from air inlet 206 to exit 208 that is sufficiently small to create an air flow resistance preventing air from re-circling toward the air inlet 206.

One or more slot fillers 100 can be used to control airflow in an electronic system by encasing multiple electronic devices 202 in a housing having multiple slots for receiving the electronic devices arranged in a stack. A cooling airstream flow is directed over the plurality of stacked electronic devices 202 from the air inlet 206 to the exit 208. Slot fillers 100 are inserted into any slots that are unoccupied by electronic devices 202. The stacked electronic devices 202 and slot fillers 100 are arranged with a selected clearance between adjacent electronic devices and/or slot fillers leaving an air flow gap from the air inlet 206 to exit 208 that is sufficiently small to create an air flow resistance preventing air from re-circling toward the air inlet 206.

The dimensions and form of the slot fillers 100 are selected to emulate the physical characteristics of an electronic device 202.

In some embodiments, the cooling airstream flow is injected into the housing from an air inlet 206 in a front portion of the housing and warm air is vented from the stacked electronic devices to an exit 208 in a rear portion of the housing.

The slot filler body 108 has a structure that creates an air channel through the housing that controls air flow resistance. In addition, the slot filler 100 includes the blanking panel 106 to cover the slot with an ornamental covering while also assisting in control of the cooling air flow.

Slot filler length can be adjusted to control extension into the housing to accommodate different sized electronic devices 202.

Referring again to FIG. 1, the cabinet 104 has a frontal surface 110 and a rear surface 112. Lateral columns 114 are attached to the frontal surface 110 on lateral ends of the multiple slots. The blanking panel 106 attaches to the columns 114. In some systems 102, the blanking panel 106 may be attached using screws, tabs, slots, clasps, or any other suitable mechanism for securing structural members.

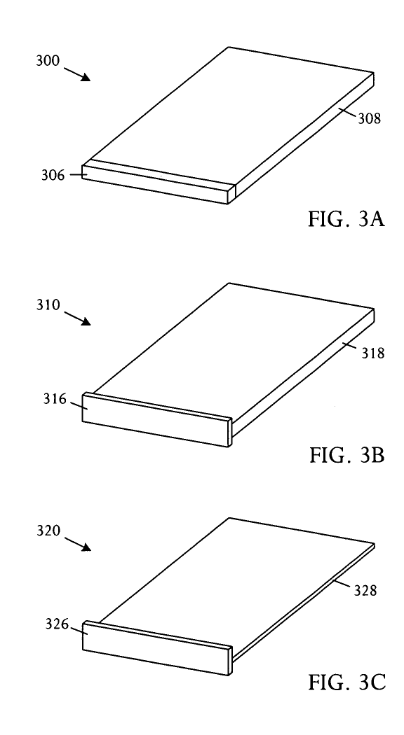

Referring to FIGS. 3A, 3B, and 3C, several perspective pictorial views show examples of slot filler 300, 310, and 320 embodiments. The blanking panels 306, 316, and 326 are typically cosmetic plates that are used to cover open spaces in the cabinet and to facilitate controlled airflow. The blanking panel 306, 316, and 326 is constructed from any suitable material such as sheet metal and/or plastic. Similarly, the body 308, 318, and 328 is constructed from sheet metal and/or plastic.

FIG. 3A shows an embodiment in which the shape of the body 308 is approximately a rectangular polyhedron with width and thickness dimensions that are approximately the same as those of the blanking panel 306. FIG. 3B depicts an embodiment with the body shape 318 also approximately a rectangular polyhedron with width and thickness dimensions that are smaller than the dimensions of the blanking panel 316 so that the panel forms a cosmetic slot cover that is larger than the internal slot. FIG. 3C illustrates an embodiment with the body shape 328 arranged as approximately a rigid rectangular plate with the blanking panel 326 extending to cover the slot.

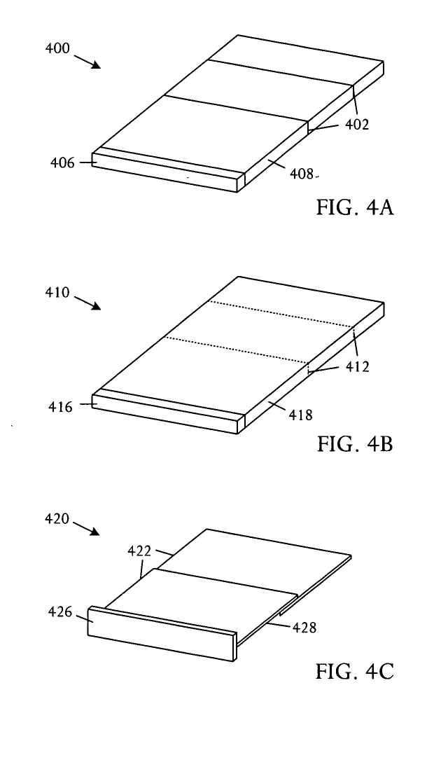

Referring to FIGS. 4A, 4B, and 4C, multiple perspective pictorial views show examples of adjustable-length slot filler embodiments 400, 410, and 420. The slot filler structures 400, 410, and 420 each have respective blanking panels 406, 416, and 426, and bodies 408, 418, and 428. In some embodiments, the bodies 408, 418, and 428 are fabricated such that the body length is adjustable to accommodate adjacent electronic devices or other objects with different lengths using various common adjustment techniques. The illustrative bodies 408, 418, and 428 have adjustable lengths for extension into the cabinet a controlled depth.

FIG. 4A shows a slot filler 400 with a telescoping body 408 with one or more telescoping joints 402 that enable length adjustment. FIG. 4B shows an embodiment of a slot filler 410 with perforation lines 412 or break lines formed by relative weakening of the body structure at selected distances from the front blanking panel 416. FIG. 4C depicts an embodiment of a slot filler 420 with a body shape 428 arranged as approximately two or more rigid rectangular plates 422 with a rail or other sliding mechanism that enables the plates 422 to slide relative to one another to extend the slot filler length. Other known techniques can be used to enable length adjustment.

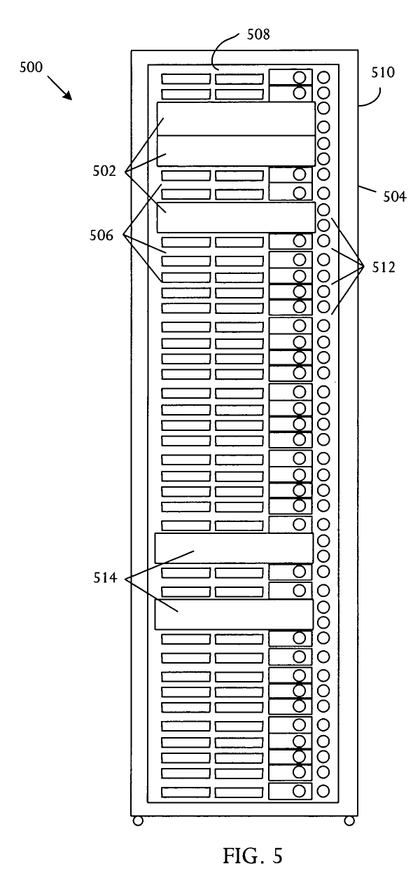

Referring to FIG. 5, a perspective pictorial diagram depicts an embodiment of a system 500 that can utilize one or more slot fillers 502. The system 500 comprises a rack cabinet 504 that can hold a plurality of stacked electronic devices 506. An air inlet 508 and exit 510 are coupled to mutually opposing sides of the cabinet 504. The cabinet 504 contains a plurality of slots 512 that can secure the stacked electronic devices 506 and one or more slot fillers 502.

A slot filler 502 comprises a blanking panel 514 capable of covering an entry opening of a slot 512 that is unoccupied by an electronic device 506. Interior to the cabinet 504, the slot filler 502 has a body coupled to the blanking panel 514 that emulates dimensions of an electronic device 506 and has a thickness selected so that clearance between the slot filler 502 and an adjacent electronic device 506 leaves an air flow gap from the air inlet to exit that is sufficiently small to create an air flow resistance preventing air from re-circling toward the air inlet 508.

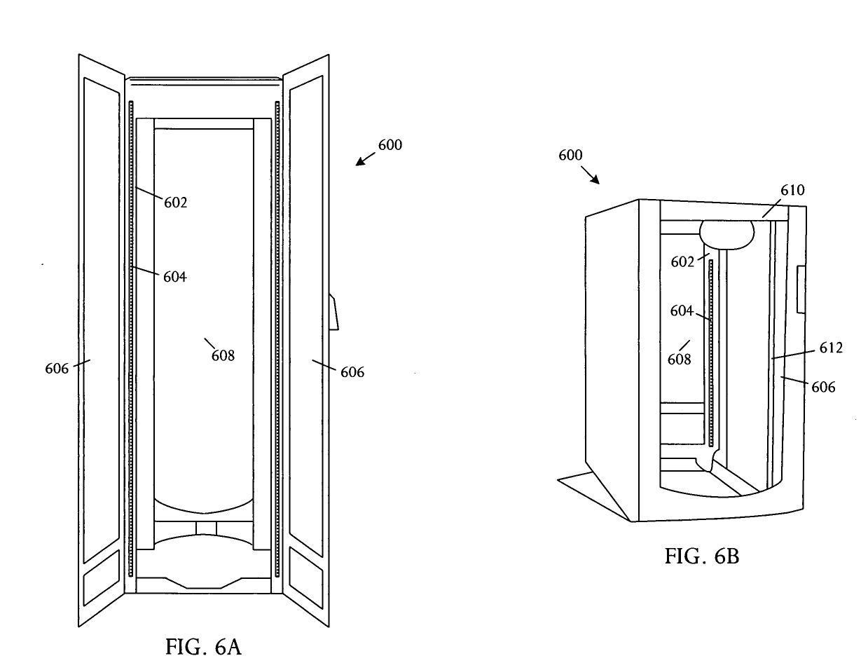

Referring to FIGS. 6A and 6B, a pair of perspective pictorial diagrams show examples of cabinets 600 that can be used in system embodiments using one or more slot fillers. The illustrative cabinets 600 have a frame 602 and rail 604 design that accepts and supports multiple various electronic devices such as servers, computer systems, storage devices, communication devices, and the like. The frame 602 and rail 604 structure forms a plurality of slots into which the electronic devices and slot fillers can be inserted. The cabinets 600 have fully perforated front 606 and rear 608 doors that supply efficient convection cooling and ventilation, while facilitating visibility. In the embodiments shown in FIGS. 6A and 6B, the air inlet is formed by the perforated front door 606 and the exit formed by the perforated rear door 608.

The cabinet 600 has a frontal surface 610 and columns 612 coupled to the frontal surface on lateral ends of the plurality of slots. The blanking panel of the slot fillers can attach to the columns 612.

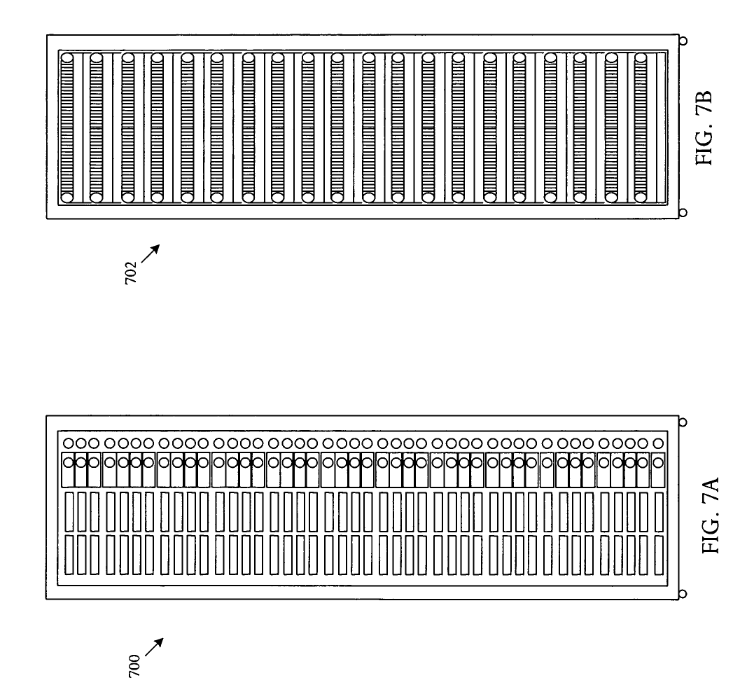

Referring to FIGS. 7A and 7B, two frontal pictorial diagrams illustrate examples of electronic systems 700 and 702, respectively, which can use the illustrative slot fillers to control exhaust air re-circulation. Various racks have capacity to hold different numbers of servers per rack, various power requirements, and different levels of heat load and cooling criteria. The sizes of housed electronic devices may vary and the dimensions of the slot fillers may vary accordingly. In various systems, the clearance between devices and cooling capacity can be selected to assure elimination of re-circulation.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, the specific examples are systems compliant with EIA standards and form factors. The illustrative structures and techniques may be used with systems of any standard and size. Also, the discussion describes contained electronic devices including servers, computer systems, communication equipment, and storage devices. The filler panels can be used in systems using any type of electronic equipment that can be mounted in racks. The disclosed systems, devices, and methods may be used with any suitable electronic devices.

1. A slot filler adapted for usage in a rack cabinet and configured to accept a plurality of stacked housing-contained electronic devices, the cabinet having an air inlet and exit on mutually opposing sides and a plurality of slots capable of securing the stacked electronic devices, the slot filler comprising:
a blanking panel adapted to cover an entry opening of an unoccupied slot; and
a body coupled to the blanking panel that emulates dimensions of a housing-contained electronic device and has a thickness selected so that clearance between the slot filler and an adjacent housing-contained electronic device leaves an air flow gap from the air inlet to exit that is sufficiently small to create an air flow resistance preventing air from re-circling toward the air inlet.

2. The slot filler according to claim 1 wherein:
the cabinet has a frontal surface and columns coupled to the frontal surface on lateral ends of the plurality of slots; and
the blanking panel attaches to the columns.

3. The slot filler according to claim 1 wherein:
the blanking panel is a cosmetic plate that is used to cover open spaces in the cabinet and to facilitate controlled airflow and is constructed from sheet metal and/or plastic; and
the body is constructed from sheet metal and/or plastic.

4. The slot filler according to claim 1 wherein the slot filler is adapted for usage in a rack cabinet configured to accept a plurality of stacked standard electronic equipment 1U devices having a box structure, the slot filler comprising:
a blanking panel configured to cover the unoccupied slot entry opening; and
a box-structured body coupled to the blanking panel that emulates dimensions of the 1U electronic device and has a thickness selected so that clearance between the slot filler and an adjacent electronic device and/or slot filler leaves an air flow gap from the air inlet to exit that prevents air from re-circling toward the air inlet.

5. The slot filler according to claim 1 wherein:
the body shape is approximately a rectangular polyhedron.

6. The slot filler according to claim 1 wherein:
the body shape is approximately a rigid rectangular plate.

7. The slot filler according to claim 1 wherein;
the body has an adjustable length for extension into the cabinet a controlled depth, the body being selected from a group of bodies consisting of a telescoping body with at least one telescoping joint enabling length adjustment, a body with at least one perforated break line relatively weakening the body structure at selected deaths into the rack cabinet, and a body including a plurality of rigid rectangular plates with a sliding mechanism enabling the plates to slide relative to one another.

8. A system comprising:
a rack cabinet adapted to hold a plurality of stacked housing-contained electronic devices;
an air inlet and exit coupled to mutually opposing sides of the cabinet;
a plurality of slots contained within the cabinet and adapted to secure the stacked housing-contained electronic devices; and
a slot filler comprising:
a blanking panel capable of covering an entry opening of a an unoccupied slot; and
a body coupled to the blanking panel that emulates dimensions of a housing-contained electronic device and has a thickness selected so that clearance between the slot filler and an adjacent housing-contained electronic device leaves an air flow gap from the air inlet to exit that is sufficiently small to create an air flow resistance preventing air from re-circling toward the air inlet.

9. The system according to claim 8 wherein:
the cabinet has a frontal surface and columns coupled to the frontal surface on lateral ends of the plurality of slots; and
the blanking panel attaches to the columns.

10. The system according to claim 8 wherein;
the blanking panel is a cosmetic plate that is used to cover open spaces in the cabinet and to facilitate controlled airflow and is constructed from sheet metal and/or plastic; and
the body is constructed from sheet metal and/or plastic.

11. The system according to claim 8 wherein the slot filler is adapted for usage in a rack cabinet configured to accept a plurality of stacked standard electronic equipment 1U devices having a box structure, the slot filler comprising:
a blanking panel configured to cover the unoccupied slot entry opening; and
a box-structured body coupled to the blanking panel that emulates dimensions of the 1U electronic device and has a thickness selected so that clearance between the slot filler and an adjacent electronic device and/or slot filler leaves an air flow gap from the air inlet to exit that prevents air from re-circling toward the air inlet.

12. The system according to claim 8 wherein:
the body shape is approximately a rectangular polyhedron.

13. The system according to claim 8 wherein:
the body shape is approximately a rigid rectangular plate.

14. The system according to claim 8 wherein:
the body has an adjustable length for extension into the cabinet a controlled depth, the body being selected from a group of bodies consisting of a telescoping body with at least one telescoping joint enabling length adjustment, a body with at least one perforated break line relatively weakening the body structure at selected depths into the rack cabinet, and a body including a plurality of rigid rectangular plates with a sliding mechanism enabling, the plates to slide relative to one another.

15. A method of controlling airflow in an electronic system comprising:
encasing a plurality of housing-contained electronic devices in a housing having multiple slots for receiving the housing-contained electronic devices arranged in a stack;
directing a cooling airstream flow over the plurality of stacked housing-contained electronic devices from an air inlet to an exit;
inserting a slot filler within any unoccupied slots between the plurality of stacked housing-contained electronic devices; and
arranging the plurality of stacked housing-contained electronic devices and slot fillers with a selected clearance between adjacent housing-contained electronic devices and/or slot fillers leaving an air flow gap from the air inlet to exit that is sufficiently small to create an air flow resistance preventing air from re-circling toward the air inlet.

16. The method according to claim 15 further comprising:
selecting dimensions and form of the slot fillers to emulate an a box-structured 1U electronic device.

17. The method according to claim 15 further comprising:
receiving the cooling airstream flow into the housing from an air inlet in a front portion of the housing; and
venting warm air from the stacked electronic devices to an exit in a rear portion of the housing.

18. The method according to claim 15 further comprising:
covering the slot filler in a an unoccupied slot with an ornamental covering.

19. The method according to claim 15 further comprising:
adjusting slot filler length for extension into the housing a controlled depth selected from a group of actions consisting of adjusting at least one telescoping joint in a telescoping body, breaking the body structure along a perforated break line relatively weakening the body structure at a selected depth into the rack cabinet, and sliding a plurality of rigid rectangular plates relative to one another.

20. A system comprising:
a housing with a plurality of slots regularly arranged in a stack for receiving multiple housing-contained electronic devices, the housing having an air inlet and an air exit for passing cooling air through the housing-contained electronic devices;
at least one housing-contained electronic device inserted into at least one of the plurality of slots; and
at least one slot filler inserted into the a slot of the plurality of slots, the slot fillers having dimensions that emulate dimensions of an a housing-contained electronic device,
the at least one housing-contained electronic device and the slot filler having an arrangement when inserted into the slots so that clearance between the adjacent slot fillers and/or housing-contained electronic device is an air flow gap that extends from the air inlet to the air exit that is sufficiently small to create an air flow resistance preventing air from re-circling toward the air inlet.

21. A system for controlling airflow in an electronic system comprising:
means for encasing a plurality of housing-contained electronic devices;
means within the encasing means for receiving the plurality of housing-contained electronic devices arranged in a stack;
means for directing a cooling airstream flow over the plurality of stacked housing-contained electronic devices from an air inlet to an exit, and
means for filling any unoccupied receiving means,
the receiving means, electronic devices, and filling means being arranged with a selected clearance between adjacent electronic devices and/or filling means leaving an air flow gap from the air inlet to exit that is sufficiently small to create an air flow resistance preventing air from re-circling toward the air inlet.
